(19) United States
(12) Patent Application Publication
(10) Pub. No.: US 2026/0372006 A1
(43) Pub. Date: Nov. 19, 2026

(54) CHIP BONDING APPARATUS AND CHIP BONDING METHOD

(71) Applicant: SAMSUNG ELECTRONICS CO., LTD., Suwon-si (KR)

(72) Inventors: Yongjin PARK, Suwon-si (KR); Jinsan JUNG, Suwon-si (KR); Youngseok JUNG, Suwon-si (KR)

(73) Assignee: SAMSUNG ELECTRONICS CO., LTD., Suwon-si (KR)

(21) Appl. No.: 19/668,944

(22) Filed: May 6, 2026

(30) Foreign Application Priority Data
May 13, 2025 (KR) 10-2025-0062135

(51) Int. Cl. H10P 72/50; H10P 72/00

(52) U.S. Cl. CPC H10P 72/50; H10P 72/0438; H10P 72/0616

(57) ABSTRACT

A chip bonding apparatus includes a support configured to fix an edge portion of a bottom surface of a substrate on which a plurality of chip structures are positioned; a tilting member configured to tilt the support; a sensor configured to measure a degree of warpage of the substrate; an upper bonding member positioned to face a top surface of the substrate and configured to pressurize and heat a top surface of the chip structure; and a lower bonding member positioned to face the bottom surface of the substrate and configured to pressurize and heat at least a portion of the bottom surface of the substrate, wherein the tilting member tilts the support such that an axis vertically penetrating through a horizontal cross-section of the support is tilted from the Z-axis.

### CROSS-REFERENCE TO RELATED APPLICATION

This application is based on and claims priority under 35 U.S.C. §119 to Korean Patent Application No. 10-2025-0062135, filed on May 13, 2025, in the Korean Intellectual Property Office, the disclosure of which is incorporated by reference herein in its entirety.

### BACKGROUND

The inventive concept relates to a chip bonding apparatus and a chip bonding method, and more particularly, to a chip bonding apparatus including bonding heads each including a heat source at each of an upper portion and a lower portion, and a chip bonding method.

As electronic devices become smaller, flip chip type semiconductor chips that do not use wire bonding are being widely used. A semiconductor chip in the form of the flip chip have a number of electrodes formed on the bottom surface of the semiconductor chip and is bonded to connection terminals formed on a substrate to which the semiconductor chip is to be mounted through solder bumps.

Thermal compression bonding is used as a method for bonding a semiconductor chip in the form of a flip chip. The thermal compression bonding is performed by using a bonding head equipped with a bonding tool and a heater, and a semiconductor chip is heated by heating the heater while the semiconductor chip is being pressurized by the bonding tool. Therefore, to achieve high mounting quality, a semiconductor chip needs to be pressurized and heated uniformly throughout.

Recently, a technology has been developed to vertically stack a plurality of semiconductor chips on a substrate using solder bumps. At this time, as the number of semiconductor chips being stacked increases, warpage of the substrate occurs, and thus problems such as poor bonding of semiconductor chips and cracks occur due to warpage of the substrate.

### SUMMARY

The inventive concept provides a chip bonding apparatus and a chip bonding method with improved bonding reliability.

In addition, the technical goals to be achieved by the inventive concept are not limited to the technical goals mentioned above, and other technical goals may be clearly understood by one of ordinary skill in the art from the following descriptions.

According to an aspect of the inventive concept, there is provided a chip bonding apparatus.

The chip bonding apparatus includes a support configured to fix an edge portion of a bottom surface of a substrate on which a plurality of chip structures are positioned; a tilting member engaged to the support and configured to tilt the support; a sensor configured to measure a degree of warpage of the substrate; an upper bonding member positioned to face a top surface of the substrate and configured to pressurize and heat a top surface of the chip structure; and a lower bonding member positioned to face the bottom surface of the substrate and configured to pressurize and heat at least a portion of the bottom surface of the substrate, wherein the tilting member tilts the support such that an axis vertically penetrating through a horizontal cross-section of the support is tilted from the Z-axis.

The chip bonding apparatus includes a support configured to fix an edge portion of a bottom surface of a substrate having a smile warpage shape and on which a plurality of chip structures are positioned; a sensor configured to measure a degree of warpage of the substrate; a tilting member configure to tilt the support such that an axis vertically penetrating through the horizontal cross section of the support is tilted from the Z axis, and to horizontally and vertically move the support; an upper bonding member positioned to face a top surface of the substrate and configured to pressurize and heat a top surface of the chip structure; and a lower bonding member positioned to face the bottom surface of the substrate and configured to pressurize and heat at least a portion of the bottom surface of the substrate, wherein each of the upper bonding member and the lower bonding member moves in the vertical direction, and wherein the tilting member is coupled to and separated from the support.

The chip bonding apparatus includes a support configured to fix an edge portion of a bottom surface of a substrate having a smile warpage shape and on which a plurality of chip structures are positioned; a tilting member engaged to the support and configured to tilt the support such that an axis vertically penetrating through the horizontal section of the support is tilted from the Z-axis, move the support horizontally and vertically, and including a first bridge and a second bridge each having a semicircular ring-like shape in a vertical section; a sensor configured to measure a degree of warpage of the substrate; an upper bonding member positioned to face a top surface of the substrate and configured to pressurize and heat a top surface of the chip structure; a lower bonding member positioned to face the bottom surface of the substrate, configured to pressurize and heat at least a portion of the bottom surface of the substrate, and including a lower bonding head, a connecting bar extending horizontally on a bottom surface of the lower bonding head, and support bars extending vertically downward from one end and the other end of the connecting bar, respectively; and a controller configured to control the tilting member to be tilted such that the chip structure is parallel to the Z axis based on the degree of warpage of the substrate provided from the sensor, wherein the first bridge and the second bridge are orthogonal to each other when viewed from above in the vertical direction, an inner diameter of the first bridge is greater than an outer diameter of the second bridge, and the tilting member further includes a first driving unit configured to rotate the first bridge around the X-axis, and a second driving unit configured to rotate the second bridge around the Y-axis.

According to another aspect of the inventive concept, there is provided a chip bonding method.

The chip bonding method includes fixing a substrate having a plurality of chip structures positioned on the top surface on a support; measuring warpage of the substrate using a sensor; tilting a tilting member based on the measured warpage of the substrate to arrange a chip structure to be bonded from among the chip structures to be parallel to the Z axis; horizontally moving the support such that the top surface of the chip structure and the top surface of an upper bonding member face each other and the bottom surface of the substrate, which overlaps the chip structure in a vertical direction, faces a lower bonding member; and vertically moving the upper bonding member and the lower bonding member to bond the chip structure.

According to embodiments, the sensor re-measures the warpage of the substrate after any one of the plurality of chip structures is bonded.

According to embodiments, the tilting member includes a first bridge and a second bridge, each of the first bridge and the second bridge have a vertical cross-section with a semicircular ring-like shape, the first bridge and the second bridge are orthogonal to each other when viewed from above in a vertical direction, and the support tilts according to rotations of the first bridge and the second bridge.

According to embodiments, the tilting member further includes a first driving unit configured to rotate the first bridge around the X-axis, and a second driving unit configured to rotate the second bridge around the Y-axis.

According to embodiments, the lower bonding member includes a lower bonding head, a connecting bar extending horizontally on a bottom surface of the lower bonding head, and support bars extending vertically downward from one end and the other end of the connecting bar, respectively.

According to embodiments, the connecting bar is staggered at a certrain angle with respect to each of the first bridge and the second bridge when viewed from above in a vertical direction.

According to embodiments, the tilting member comprises a plurality of actuators that are coupled to the bottom surface of the support, have a shape extending in a vertical direction, have lengths adjusted in the vertical direction, are provided spaced apart from one another, and operate independently of one another.

According to embodiments, four actuators are provided and the four actuators are arranged at an angle of 90 degrees around the center of the support in a horizontal cross-section.

According to embodiments, the support has a circular ring-like shape having an opening at the center thereof.

According to embodiments, the substrate has a smile warpage shape.

### BRIEF DESCRIPTION OF THE DRAWINGS

Embodiments of the inventive concept will be more clearly understood from the following detailed description taken in conjunction with the accompanying diagrams in which:

FIG. 1 is a schematic perspective view of a chip bonding apparatus according to embodiments;

FIG. 2 is a cross-sectional view taken along a line A1-A1' of FIG. 1;

FIG. 3 is a cross-sectional view taken along a line A2-A2' of FIG. 2;

FIG. 4 is a schematic plan view of a support and a tilting member of FIG. 1;

FIG. 5 is a schematic perspective view of a lower bonding member of FIG. 1;

FIG. 6 is an enlarged view of a portion AA of FIG. 2;

FIGS. 7A,7B and 7C are cross-sectional views for describing the operation of a chip bonding apparatus according to the inventive concept;

FIG. 8 is a perspective view showing the operation of the first bridge and the second bridge of FIG. 1 according to an embodiment;

FIG. 9 is a perspective view schematically showing a chip bonding apparatus according to embodiments;

FIG. 10 is a plan view schematically showing the support and the tilting member of FIG. 9;

FIG. 11 is a schematic perspective view of a chip bonding apparatus according to embodiments;

FIG. 12 is a plan view schematically showing the support and the tilting member of FIG. 11; and

FIG. 13 is a flowchart for describing a chip bonding method according to embodiments.

### DETAILED DESCRIPTION OF THE EMBODIMENTS

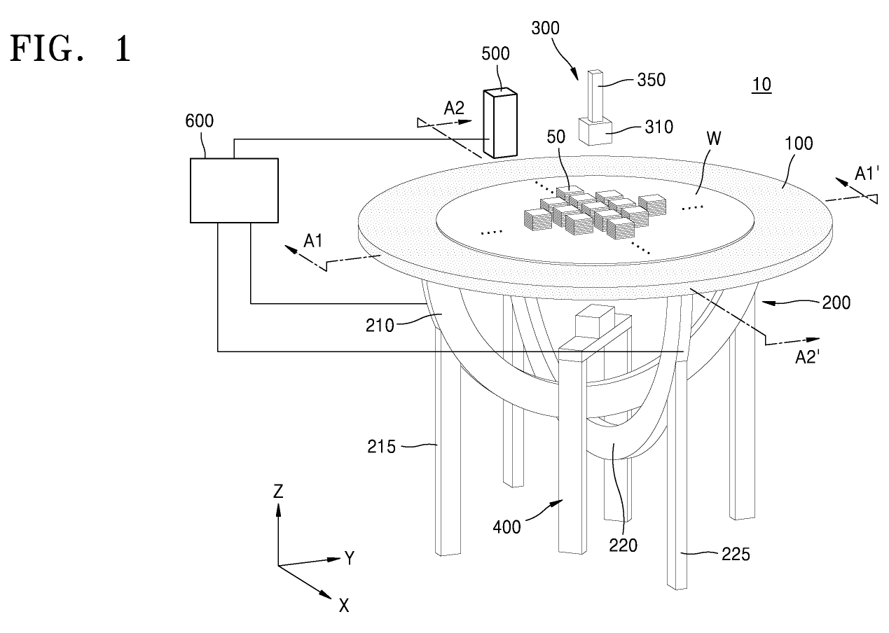

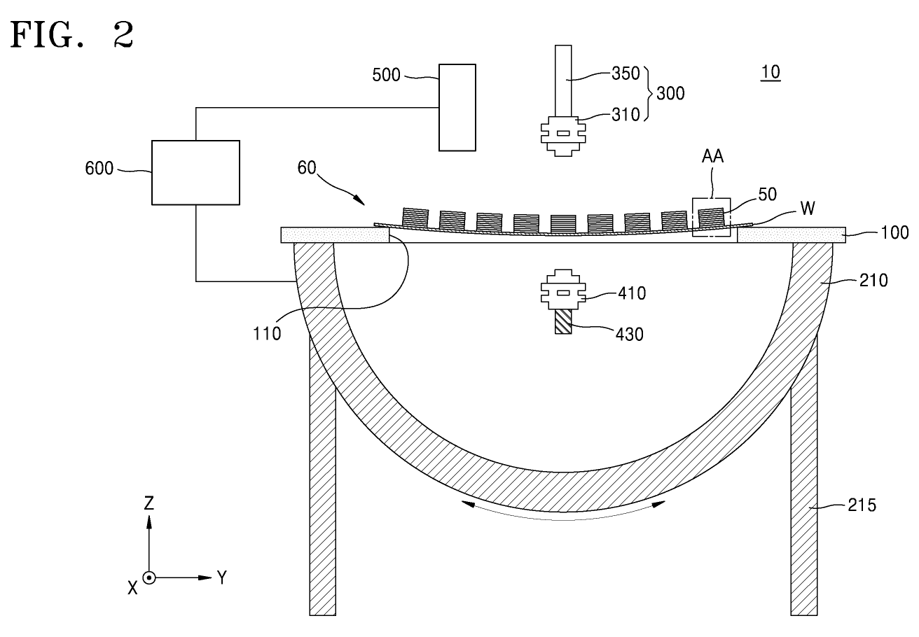

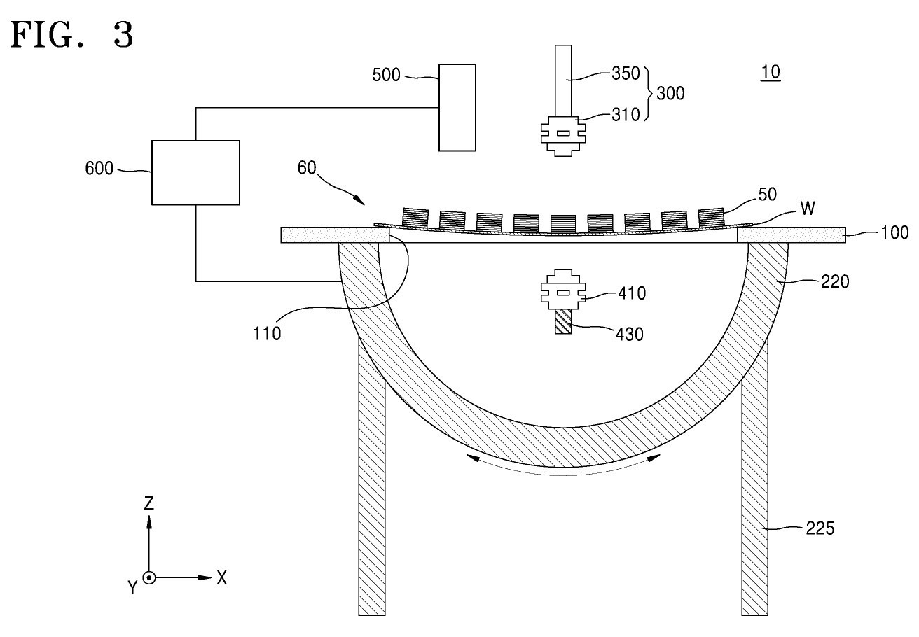

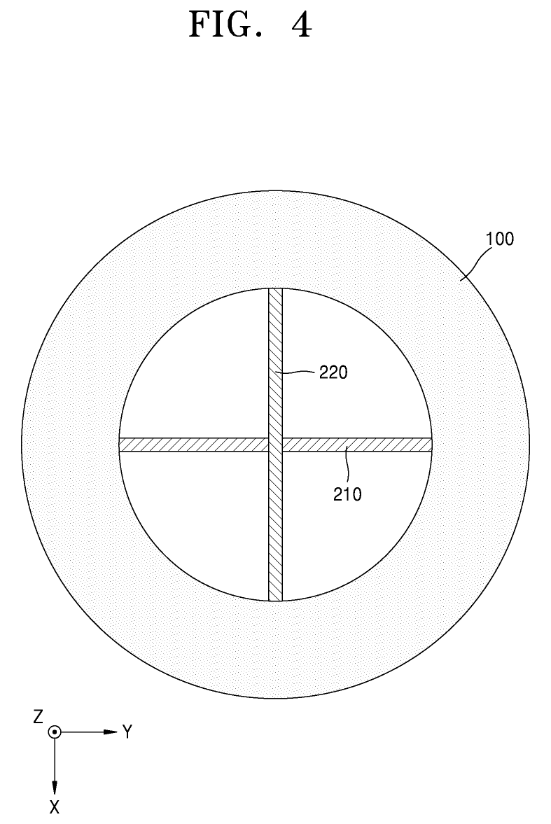

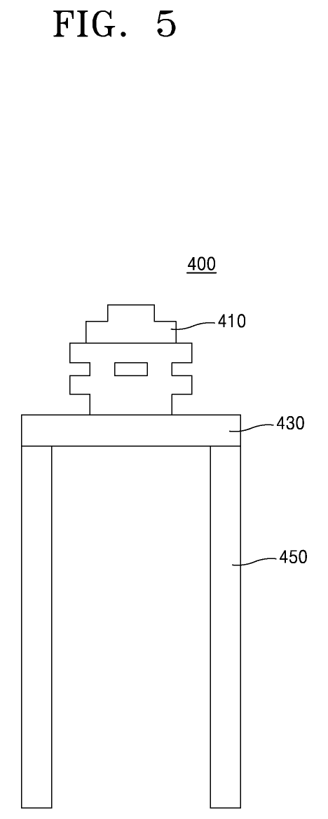

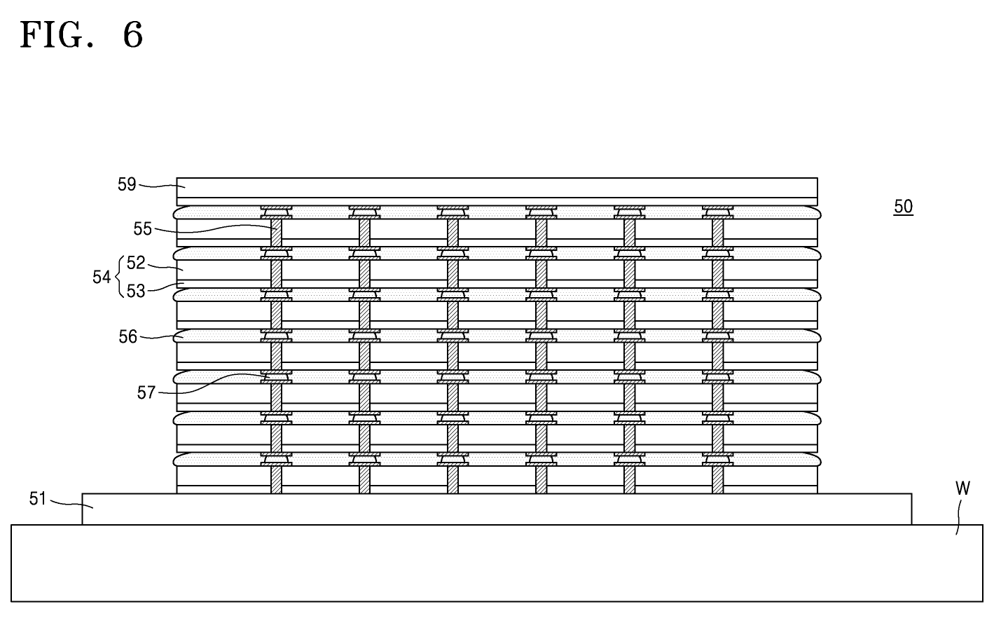

FIG. 1 is a schematic perspective view of a chip bonding apparatus according to embodiments. FIG. 2 is a cross-sectional view taken along a line A1-A1' of FIG. 1. FIG. 3 is a cross-sectional view taken along a line A2-A2' of FIG. 2. FIG. 4 is a schematic plan view of a support and a tilting member of FIG. 1. FIG. 5 is a schematic perspective view of a lower bonding member of FIG. 1. FIG. 6 is an enlarged view of a portion AA of FIG. 2.

Referring to FIGS. 1 - 6, a chip bonding apparatus 10 according to the inventive concept may include a support 100, a tilting member 200, a lower bonding member 400, an upper bonding member 300, and a sensor 500.

The support 100 may be configured to support a substrate W. In detail, the support 100 may be configured to support an edge portion of the bottom surface of the substrate W. Here, the substrate W may have a circular plate-like shaped structure like a wafer. Also, the edge portion may be understood as an edge region adjacent to the outer periphery of the substrate W from among regions formed on the bottom surface of the substrate W, and as a region distinct from the center of the substrate W. Also, the edge portion may also be understood as an outer edge portion that is in contact with and supported by the support 100 on the bottom surface of the substrate W.

A plurality of chip structures 50 may be positioned on the substrate W. The plurality of chip structures 50 may be positioned to be spaced apart from one another in the horizontal direction X or/and Y. A chip structure 50 will be described in detail with reference to FIG. 6.

According to embodiments, the support 100 may have a disc-like shape having an opening 110 formed in the center. For example, the support 100 may have a ring-like shape or annular shape. The support 100 may have a doughnut-like shape when viewed from above in the vertical direction Z. The edge portion of the bottom surface of the substrate W may physically contact the top surface of the support 100.

The support 100 may include an adsorption portion positioned on the top surface of the support 100. The adsorption portion may be configured to fix and separate the bottom surface of the substrate W placed on the top surface of the support 100. When the edge portion of the bottom surface of the substrate W is placed on the top surface of the support 100, the adsorption portion may fix the substrate W to the support 100 or separate the substrate W from the support 100. According to embodiments, the adsorption portion may fix the edge portion of the bottom surface of the substrate W through vacuum adsorption.

The diameter of the support 100 may be greater than the diameter of the substrate W. In the same sense, the support 100 may have a greater outer diameter than the substrate W. Therefore, the support 100 may stably support and fix the substrate W. Also, since an opening 110 is formed in the center of the support 100, even when warpage occurs in the substrate W, the support 100 may stably support and fix the substrate W. Since the support 100 has a structure having an open center, even when the substrate W is bent, the substrate W placed on the support 100 may be prevented from coming into contact with the support 100.

According to some embodiments, the substrate W may have a warpage shape in which the vertical level of the center of the substrate W is lower than the vertical level of the edge portion of the substrate W depending on environmental conditions. Here, a bending shape in which the vertical level of the center of the substrate W is lower than the vertical level of the edge portion of the substrate W may be understood as a smile bending shape. However, the bending shape of the substrate W is not limited to a smile bending shape, and the substrate W may have a crying bending shape in which the vertical level of the center of the substrate W is higher than the vertical level of the edge portion of the substrate W depending on environmental conditions. However, for convenience, in this specification, it is described that the substrate W has a smile bending shape, and the inventive concept may also be applied to a case where the substrate W has a crying bending shape.

The tilting member 200 engaged to the support 100 may be configured to tilt the support 100. The tilting member 200 may be configured to tilt the support 100 in each of the X-axis direction and the Y-axis direction. The support 100 may have the degree of freedom to tilt in each of the X-axis direction and the Y-axis direction according to the movement of the tilting member 200. Here, the tilting of the support 100 in the X-axis direction may be understood as the rotation of the support 100 in the Y-axis direction in the cross-section along the XZ plane. Also, the tilting of the support 100 in the Y-axis direction may be understood as the rotation of the support 100 in the X-axis direction in the cross-section along the YZ plane.

The tilting member 200 may tilt the support 100 such that an axis that vertically penetrates through the horizontal cross-section of the support 100 is tilted from the Z axis.

Also, the tilting of the support 100 in the X-axis direction may mean that the center of the support 100 in the cross-section along the XZ plane is fixed and the vertical level of the support 100 changes according to a change in the level of the support 100 in the X direction based on the center of the support 100. Also, the tilting of the support 100 in the Y-axis direction may mean that the center of the support 100 in the cross-section along the YZ plane is fixed and the vertical level of the support 100 changes according to a change in the level of the support 100 in the Y direction based on the center of the support 100.

The support 100 may be tilted in any direction around an axis that penetrates through the virtual center of the cross-section of the support 100 along the XY plane in the vertical direction Z by the tilting member 200. This may be understood as, when the support 100 is assumed to be a virtual plane, the virtual plane, i.e. the support 100, is tilted along a normal vector of the virtual plane as the normal vector of the virtual plane is tilted along the normal vector.

According to some embodiments, the tilting member 200 may be coupled to the bottom surface of the support 100. According to some embodiments, the tilting member 200 may be coupled to and separated from the support 100. Since the tilting member 200 may be combined to and separated from the support 100, repair and maintenance of the support 100 and the tilting member 200 may be smoothly performed, and the positional relationship between the support 100 and the tilting member 200 may be easily adjusted. According to some embodiments, the tilting member 200 may be integral with the support 100. When the tilting member 200 is formed integrally with the support 100, the support 100 may be stably tilted by the tilting member 200.

According to embodiments, the tilting member 200 may include a first bridge 210 and a second bridge 220, as shown in FIGS. 1 - 3. According to embodiments, the first bridge 210 and the second bridge 220 may each have a semicircular ring-like shape in a vertical cross-section. For example, the first bridge 210 may have a semicircular ring-like shape in the cross-section along the YZ plane as shown in FIG. 2. Also, the second bridge 220 may have a semicircular ring-like shape in the cross-section along the XZ plane as shown in FIG. 3. Here, a semicircular shape may be defined as a concept that includes not only a semicircular shape but also a semi-elliptical shape.

According to embodiments, the first bridge 210 and the second bridge 220 may each have an arch-like shape having a semicircular curved cross-section. According to embodiments, the first bridge 210 and the second bridge 220 may each have a C-shaped cross-section in a vertical cross-section.

According to embodiments, the first bridge 210 and the second bridge 220 may not contact each other. For example, the inner diameter of the first bridge 210 may be greater than the outer diameter of the second bridge 220. Therefore, the first bridge 210 and the second bridge 220 may not contact each other.

According to embodiments, the inner surfaces and the outer surfaces of each of the first bridge 210 and the second bridge 220 may have the lowest vertical level at the center of the support 100. Here, the outer surface may be understood as the surface facing the floor, and the inner surface may be understood as the surface facing the support. At this time, when the lowest vertical level on the inner surface of the first bridge 210 is defined as a first level and the lowest vertical level on the outer surface of the second bridge 220 is defined as a second level, the first level may have a lower vertical level than the second level. Therefore, the first bridge 210 and the second bridge 220 may not meet each other.

The first bridge 210 and the second bridge 220 may rotate. According to embodiments, the first bridge 210 may rotate around the X-axis on the YZ plane, and the second bridge 220 may rotate about the Y-axis on the XZ plane.

The first bridge 210 and the second bridge 220 may rotate independently. Therefore, the tilting member 200 may have a degree of freedom to tilt along each of the X-axis and the Y-axis. As the first bridge 210 and the second bridge 220 rotate, the support 100 coupled with the first bridge 210 and the second bridge 220 may rotate. Therefore, the support 100 may be tilted along each of the X-axis and the Y-axis. Depending on the change in the positional relationship between the first bridge 210 and the second bridge 220, the support 100 may be tilted in any direction with respect to the Z axis.

According to embodiments, the first bridge 210 and the second bridge 220 may have shapes that are orthogonal to each other when viewed from above in the vertical direction Z, as shown in FIG. 4.

The tilting member 200 may include a first driving unit 215 and a second driving unit 225. The rotation of the first bridge 210 and the second bridge 220 may be performed by the first driving unit 215 and the second driving unit 225. For example, the rotation of the first bridge 210 may be performed by the first driving unit 215, and the rotation of the second bridge 220 may be performed by the second driving unit 225.

According to embodiments, the first driving unit 215 and the second driving unit 225 may each be provided as a plurality of units. For example, as shown in FIGS. 2 and 3 , the first driving unit 215 and the second driving unit 225 may each be provided as two units. However, the number of first driving units 215 and the number of second driving units 225 are not limited thereto, and the first driving units 215 and the second driving units 225 may each be provided as a single unit or as three or more units.

According to embodiments, two first driving units 215 may be positioned at substantially the same distance from the center of the first bridge 210. Also, two second driving units 225 may be positioned at substantially the same distance from the center of the second bridge 220.

Each of the first driving unit 215 and the second driving unit 225 may be relatively fixed in relation to each of the first bridge 210 and the second bridge 220. For example, when the first bridge 210 is rotated by the first driving unit 215, the first driving unit 215 may not move relatively with respect to the first bridge 210. Similarly, when the second bridge 220 is rotated by the second driving unit 225, the second driving unit 225 may not move relatively with respect to the second bridge 220.

The first driving unit 215 and the second driving unit 225 may move linearly in each of the horizontal direction X and/or Y and the vertical direction Z. Therefore, the first bridge 210 coupled with the first driving unit 215 and the second bridge 220 coupled with the second driving unit 225 may also move linearly in each of the horizontal direction X and/or Y and the vertical direction Z. Similarly, the support 100 may also move linearly in each of the horizontal direction X and/or Y and the vertical direction Z according to the linear movement of the first driving unit 215 and the second driving unit 225. Therefore, even when the X-coordinates and Y-coordinates of the upper bonding member 300 and the lower bonding member 400 are fixed, each of the plurality of chip structures 50 positioned spaced apart from one another on the support 100 may be bonded.

The upper bonding member 300 may be positioned to face the top surface of the substrate W. The upper bonding member 300 may include an upper bonding head 310 and an upper bar 350. The upper bonding head 310 may be configured to pressurize and heat the top surface of the chip structure 50positioned on the substrate W. The surface of the upper bonding head 310 that comes into contact with the top surface of the chip structure 50 may have a flat shape. The upper bar 350 may move the upper bonding head 310 in the vertical direction Z. The upper bonding head 310 may be moved in the vertical direction Z by the upper bar 350. As the upper bonding head 310 is driven vertically by the upper bar 350, the upper bonding head 310 may transmit a force directed downward in the vertical direction Z onto the top surface of the chip structure 50. Also, the upper bonding head 310 may include a heat source. The upper bonding head 310 is heated by the heat source and may transfer heat to the chip structure 50 through heat conduction by coming into contact with the top surface of the chip structure 50.

According to embodiments, the upper bonding member 300 may pressurize and heat the top surface of one chip structure 50. However, According to some embodiments, the upper bonding member 300 may pressurize and heat the top surface of each of the plurality of chip structures 50 at once.

The lower bonding member 400 may be positioned to face the bottom surface of the substrate W. The lower bonding member 400 may include a lower bonding head 410, a connecting bar 430, and a support bar 450 as shown in FIG. 5. The lower bonding head 410 may be configured to pressurize and heat at least a portion of the bottom surface of the substrate W. Here, the at least a portion of the bottom surface of the substrate W may be understood as a portion that overlaps with the chip structure 50 heated and pressurized by the upper bonding head 310 in the vertical direction Z. The surface of the lower bonding head 410 that comes into contact with the bottom surface of the substrate W may have a flat shape. The lower bonding head 410 may include a heat source. The lower bonding head 410 is heated by the heat source and may transfer heat to a portion of the bottom surface of the substrate W through heat conduction by coming into contact with the bottom surface of the substrate W. The connecting bar 430 may be connected to each of the lower bonding head 410 and the support bar 450. The connecting bar 430 may have a shape extending in the horizontal direction. According to some embodiments, the connecting bar 430 may not be in contact with the first bridge 210 and the second bridge 220 as shown in FIG. 1. For example, when the first bridge 210 and the second bridge 220 are orthogonal to each other when viewed from above in the vertical direction Z, the connecting bar 430 may be staggered at a certain angle with respect to each of the first bridge 210 and the second bridge 220 when viewed from above in the vertical direction Z. According to embodiments, the connecting bar 430 may have a 45 degree angle with respect to each of the first bridge 210 and the second bridge 220 when viewed from above in the vertical direction Z.

The support bar 450 may be configured to support the connecting bar 430. According to embodiments, a plurality of support bars 450 may be provided. The support bars 450 may be located at one end and the other end of the connecting bar 430. According to embodiments, the support bar 450 may move the connecting bar 430 in the vertical direction Z. Therefore, the lower bonding head 410 coupled with the connecting bar 430 may also move in the vertical direction Z.

The chip structure 50 may include a base chip 51, a semiconductor chip 54, and a top semiconductor chip 59 as shown in FIG. 6. The chip structure 50 may include the base chip 51, the semiconductor chip 54, and the top semiconductor chip 59. The base chip 51 is a chip located at the bottom within the chip structure 50 and may be directly connected to the substrate W through bumps. According to embodiments, the base chip 51 may integrate signals of the semiconductor chip 54 stacked on top of the base chip 51 and the top semiconductor chip 59 and transmit the signals to the outside or transmit signals and power from the outside to the semiconductor chip 54 and the top semiconductor chip 59. Therefore, the base chip 51 may also be referred to as a buffer chip or a control chip in the present specification.

The base chip 51 may include various types of individual devices. The individual devices may include various microelectronic devices, e.g., a metal-oxide-semiconductor field effect transistor (MOSFET) such as a complementary metal-insulator-semiconductor transistor (CMOS transistor), a system large scale integration (LSI), an image sensor such as a CMOS imaging sensor (CIS), a micro-electro-mechanical system (MEMS), an active device, a passive device, etc. According to some embodiments, the base chip 51 may not include a memory cell. For example, a semiconductor device included in the base chip 51 may include a serial-parallel conversion circuit, a test logic circuit such as a design for test (DFT), a joint test action group (JTAG), and a memory built-in self (MBIST), a signal interface circuit such as a physical layer (PHY).

The semiconductor chip 54 may be stacked in the vertical direction Z on the base chip 51. According to embodiments, a plurality of semiconductor chips 54 may be provided. The plurality of semiconductor chips 54 may be understood as chips that are stacked in the vertical direction Z on the base chip 51 from among a plurality of chips included in the chip structure 50. A total of eight semiconductor chips 54 may be provided, from the semiconductor chip 54 located directly above the base chip 51 to the top semiconductor chip 59. However, the number of semiconductor chips 54 is not limited thereto, and 1 to 7, or 9 or more semiconductor chips 54 may be provided. The semiconductor chip 54 may also be referred to as a memory chip or a core chip.

According to embodiments, the semiconductor chip 54 may include a semiconductor substrate 52, a through electrode 55, and a semiconductor element layer 53. The semiconductor substrate 52 may have a bottom surface and a top surface facing each other. The bottom surface may be a surface facing the substrate W. The bottom surface may be referred to as an active surface, and the top surface opposite to the bottom surface may be referred to as an inactive surface.

The semiconductor substrate 52 may include silicon (Si), e.g., crystalline Si, polycrystalline Si, or amorphous Si. Alternatively, the semiconductor substrate 52 may include a semiconductor element like germanium (Ge) or a compound semiconductor like silicon carbide (SiC), gallium arsenide (GaAs), indium arsenide (InAs), and indium phosphide (InP). In addition, the semiconductor substrate 52 may have a silicon-on-insulator (SOI) structure. For example, the semiconductor substrate 52 may include a buried oxide (BOX) layer. The semiconductor substrate 52 may include a conductive region, e.g., a well doped with an impurity or a structure doped with an impurity. Also, the semiconductor substrate 52 may have various device isolation structures like a shallow trench isolation (STI) structure.

According to embodiments, the semiconductor element layer 53 may be formed on the bottom surface of the semiconductor substrate 52, which is the active surface. Individual devices may be formed within the semiconductor element layer 53. The individual devices may include various microelectronic devices, e.g., a metal-oxide-semiconductor field effect transistor (MOSFET) such as a complementary metal-insulator-semiconductor transistor (CMOS transistor), a system large scale integration (LSI), an image sensor such as a CMOS imaging sensor (CIS), a micro-electro-mechanical system (MEMS), an active device, a passive device, etc.

The through electrode 55 may be formed to penetrate through the semiconductor substrate 52 in a vertical direction. According to some embodiments, the through electrode 55 may be formed to penetrate through a portion of the semiconductor element layer 53 and the semiconductor substrate 52. The through electrode 55 may extend in the vertical direction Z from the semiconductor element layer 53 toward the top surface of the semiconductor substrate 52 and may be electrically connected to wires provided within the semiconductor element layer 53. The through electrode 55 may have a tapered shape in which the horizontal width decreases or increases as the level in the vertical direction increases. At least a portion of the through electrode 55 may have a columnar shape. The through electrode 55 may be a through-silicon via (TSV).

According to some embodiments, the plurality of semiconductor chips 54 stacked in the vertical direction Z may be stacked via bumps 57 and an adhesive layer 56. For example, the semiconductor chip 54 located at the bottom from among the plurality of semiconductor chips 54 may be stacked on the base chip 51 in a flip-chip manner through the bumps 57. Also, the semiconductor chip 54 stacked on the top surface of the semiconductor chip 54 may also be stacked in a flip chip manner through the bumps 57. Here, the bumps 57 may include, for example, micro bumps. According to embodiments, a bump 57 may have a pillar-like structure, a ball-like structure, or a solder layer. Also, the adhesive layer 56 may be provided between the base chip 51 and the lowermost semiconductor chip 54 and between the semiconductor chips 54 that are closest to each other in the vertical direction Z. According to some embodiments, the adhesive layer 56 may be a film that itself has adhesive properties. For example, the adhesive layer 56 may include a die attach film (DAF) or a non-conductive film (NCF).

According to embodiments, the length of the semiconductor chip 54 in the first horizontal direction X may be smaller than the length of the base chip 51 in the first horizontal direction X. The footprint of the semiconductor chip 54 may be smaller than the footprint of the base chip 51.

According to embodiments, the semiconductor chip 54 may include a memory chip. The memory chip may be, for example, a volatile memory chip such as dynamic random access memory (DRAM) or static random access memory (SRAM) or a non-volatile memory chip such as phase-change random access memory (PRAM), magneto-resistive random access memory (MRAM), ferroelectric random access memory (FeRAM), or resistive random access memory (RRAM). However, the inventive concept is not limited thereto, and the semiconductor chip may include a microprocessor such as a central processing unit (CPU), a graphic processing unit (GPU), or an application processor (AP), an analog component, or a logic chip such as a digital signal processor.

The sensor 500 may be configured to measure the warpage of the substrate W. The sensor 500 may measure the degree of warpage of the substrate W. According to embodiments, the sensor 500 may include a laser displacement sensor, a white light interferometer sensor, a camera-based 3D sensor, a 3D optical profiler sensor, etc. The sensor 500 may transmit the degree of warpage of the substrate W to a controller 600.

According to embodiments, the sensor 500 may measure the degree of warpage of the substrate W when the substrate W is mounted on the support 100. Also, the sensor 500 may measure the degree of warpage of the substrate W even while bonding of the chip structure 50 on the substrate W is being performed. When heat and pressure are applied to the substrate W while the chip structures 50 are being bonded onto the substrate W, the degree of warpage of the substrate W may change compared to that when it was first placed on the support 100. The sensor 500 may measure the degree of warpage of the substrate W from time to time while the bonding process is performed and transmit the degree of warpage to the controller 600.

The controller 600 may tilt the tilting member 200 based on the degree of warpage of the substrate W provided from the sensor 500 and tilt the support 100 connected to the tilting member 200. Also, the controller 600 may move the tilting member 200 linearly in the horizontal direction X or/and Y and the vertical direction Z based on the degree of warpage of the substrate W provided from the sensor 500.

In detail, the controller 600 may control the movement of the tilting member 200 such that the top surface of the chip structure 50 to be bonded is brought into contact with the upper bonding head 310 in the vertical direction Z, and the bottom surface of the substrate W that overlaps the chip structure 50 in the vertical direction Z is brought into contact with the lower bonding head 410 in the vertical direction Z. Therefore, regardless of the degree of warpage of the substrate W, the controller 600 may control the degree of rotation and the degree of linear movement of the tilting member 200 according to the degree of warpage, such that the top surface of the chip structure 50 and the upper bonding head 310 contact each other in the vertical direction Z, and the bottom surface of the substrate W and the lower bonding head 410 contact each other in the vertical direction Z.

The controller 600 may be implemented in hardware, firmware, software, or any combination thereof. For example, the controller 600 may include a computing device like a workstation computer, a desktop computer, a laptop computer, and a tablet computer. The controller 600 may include a simple controller, a complex processor like a microprocessor, a center processing unit (CPU), and a graphics processing unit (GPU), a processor configured by software, dedicated hardware, or firmware. The controller 600 may be implemented by, for example, a general-purpose computer or application-specific hardware like a digital signal processor (DSP), a field programmable gate array (FPGA), and an application specific integrated circuit (ASIC). The controller 600 may be implemented as instructions stored on a machine-readable medium that may be read and executed by one or more processors. Here, a machine-readable medium may include any mechanism for storing and/or transmitting information in a form readable by a machine (e.g., a computing device). For example, machine-readable media may include read-only memories (ROM), random access memories (RAM), magnetic disk storage media, optical storage media, and flash memory devices, and may have recorded thereon electrical, optical, acoustic, or other forms of radio frequency signals (e.g., carrier waves, infrared signals, digital signals, etc.) and any other signal.

Previously, when warping occurs in the substrate W, a step may occur in the vertical direction Z between the center and outer portions of the substrate W. This may cause the chip structures 50 positioned on the outer portion of the top surface of the substrate W to be not aligned with the Z axis and to be tilted from the Z axis. Top surfaces of the chip structures 50 that are not aligned with the Z axis do not completely contact the upper bonding head 310 in the vertical direction Z, and only a portion of the top surfaces may first come into contact with the upper bonding head 310. Likewise, the bottom surface of the substrate W that overlaps the chip structures 50 in the vertical direction Z may not be able to fully contact the lower bonding head 410 in the vertical direction Z. Therefore, the bonding reliability of the chip structure 50 decreases, and bonding instability, cracks, etc. may occur.

However, the chip bonding apparatus 10 according to the inventive concept may tilt the support 100 through the tilting member 200, and may move the support 100 horizontally and vertically through the tilting member 200. Therefore, even when a warpage occurs in the substrate W, the degree to which the chip structure 50 to be bonded is tilted from the Z-axis may be measured, and the support 100 may be tilted via the tilting member 200 such that the chip structure 50 becomes parallel to the Z-axis, and the support 100 may be moved horizontally and vertically such that the chip structure 50, the upper bonding member 300, and the lower bonding member 400 face each other, to facilitate complete bonding of the chip structure 50 to the upper bonding member 300 and the lower bonding member 400 in the vertical direction Z.

Therefore, the bonding reliability between semiconductor chips 54 within the chip structure 50 may be improved, and the occurrence of cracks within the substrate W and the chip structure 50 may be prevented.

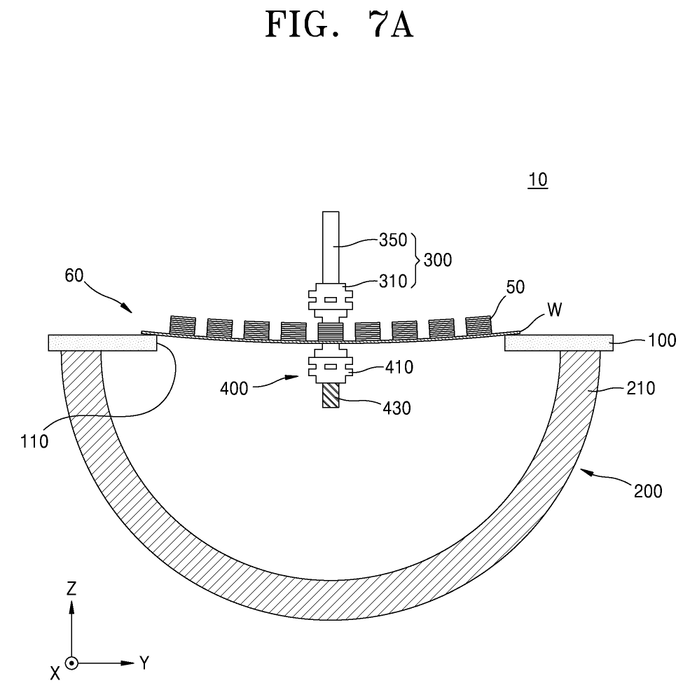

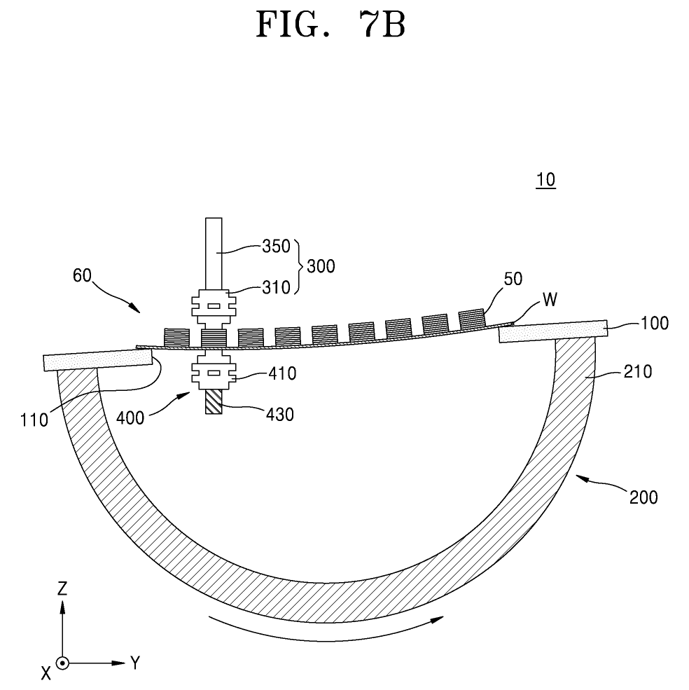

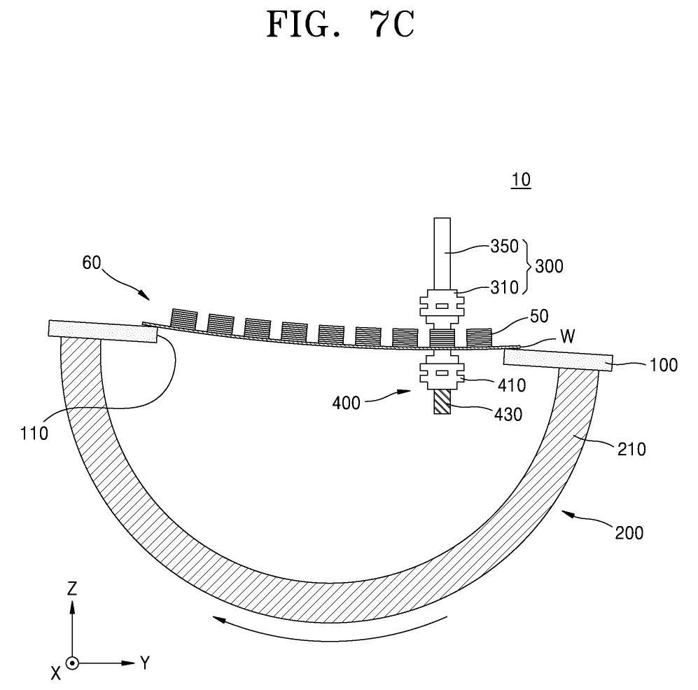

FIGS. 7A - 7C are cross-sectional views for describing the operation of a chip bonding apparatus according to the inventive concept. Descriptions identical to those already given above with reference to FIGS. 1 - 6 will be omitted, and descriptions below will focus on differences therefrom. Also, for convenience of explanation, the operation of the chip bonding apparatus is described below based on a first bridge of the chip bonding apparatus, and the chip bonding apparatus may operate through a second bridge, and may also operate through both the first bridge and the second bridge.

Referring to FIGS. 7A - 7C, the chip bonding apparatus 10 may include the support 300, the tilting member 200, the lower bonding member 400, the upper bonding member 300, and the sensor 500. According to embodiments, the substrate W fixed on the support 100 may have a smile-shaped warpage.

When the substrate W having a smile-shaped warpage is fixed to the support 100, the chip structure 50 located at the center of the substrate W may be positioned to be parallel to the Z axis. However, the chip structures 50 positioned on the substrate W are not aligned with the Z axis as the chip structures 50 are positioned further outward, and may be tilted to have a certain angle with respect to the Z axis. Here, it may be understood that the chip structure 50 being positioned parallel to the Z axis means that the axis perpendicular to the top surface and the bottom surface of the chip structure 50 is parallel to the Z axis. Also, it may be understood that the chip structure 50 being tilted to have a certain angle with respect to the Z axis means that the axis perpendicular to the top surface and the bottom surface of the chip structure 50 has a certain angle with respect to the Z axis.

For example, as shown in FIG. 7A, when bonding the chip structure 50 located at the center of the substrate W, the chip structure 50 is parallel to the Z axis, and thus the chip structure 50 may be bonded through the upper bonding member 300 and the lower bonding member 400 without the tilting member 200 operating and the support 100 being tilted.

On the other hand, as shown in FIGS. 7B and 7C, , the chip structure 50 located at the outer portion of the substrate W may be tilted to have a certain angle with respect to the Z axis. Therefore, by tilting the support 100 through the operation of the tilting member 200, the chip structure 50 located at the outer portion of the substrate W may be arranged parallel to the Z axis. Thereafter, the chip structure 50 may be bonded through the upper bonding member 300 and the lower bonding member 400.

Also, the support 100 may move horizontally and vertically through the tilting member 200. Therefore, after tilting the support 100 such that the chip structure 50 located at the outer portion of the substrate W is parallel to the Z axis, the support 100 may be moved horizontally such that the chip structure 50 overlaps with each of the upper bonding member 300 and the lower bonding member 400 in the vertical direction Z.

For example, in FIG. 7B, to bond the chip structure 50 located on the -Y direction side of the substrate W, the first bridge 210 may be rotated counterclockwise to tilt the substrate W such that that the chip structure 50 is parallel to the Z axis, and the support 100 may be horizontally moved in the +Y direction such that the chip structure 50 overlaps with each of the upper bonding member 300 and the lower bonding member 400 in the vertical direction Z. Therefore, the chip structure 50 may make seamless, face-to-face contact with the upper bonding member 300 and the lower bonding member 400.

Also, in FIG. 7C, to bond the chip structure 50 located on the +Y direction side of the substrate W, the first bridge 210 may be rotated clockwise to tilt the substrate W such that that the chip structure 50 is parallel to the Z axis, and the support 100 may be horizontally moved in the -Y direction such that the chip structure 50 overlaps with each of the upper bonding member 300 and the lower bonding member 400 in the vertical direction Z. Therefore, the chip structure 50 may 50ke seamless, face-to-face contact with the upper bonding member 300 and the lower bonding member 400.

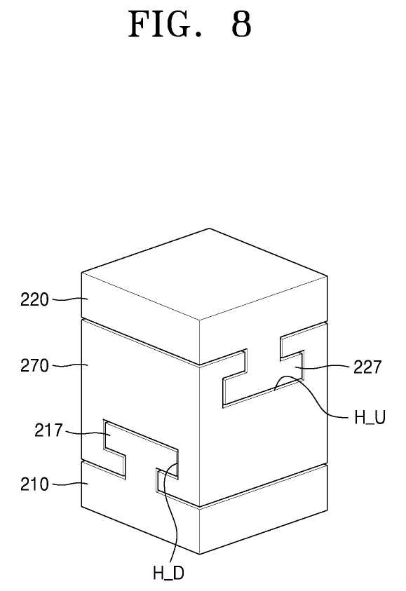

FIG. 8 is a perspective view showing the operation of the first bridge and the second bridge of FIG. 1 according to an embodiment. Descriptions identical to those already given above with reference to FIGS. 1 - 7C will be omitted, and descriptions below will focus on differences therefrom.

Referring to FIG. 8, the first bridge 210 may be located below the second bridge 220. A power member 270 may be positioned between the first bridge 210 and the second bridge 220. The power member 270 may be configured to be coupled to and separated from each of the first bridge 210 and the second bridge 220. The first bridge 210 may include a first rail 217, and the second bridge 220 may include a second rail 227. The first rail 217 may be inserted into a lower groove H_D of the power member 270, and the second rail 227 may be inserted into an upper groove H_U of the power member 270.

According to embodiments, the power member 270 is positioned between the first bridge 210 and the second bridge 220 and may have a rectangular hexahedral shape. The power member 270 may be configured to provide power to rotate the first rail 217 inserted into the lower groove H_D and power to rotate the second rail 227 inserted into the upper groove H_U.

The first bridge 210 and the second bridge 220 may rotate through the first rail 217 and the second rail 227, respectively. At this time, the power member 270 may be maintained in a fixed state. The power member 270 may provide power to rotate the first rail 217 and the second rail 227. While the power member 270 is being fixed, the first bridge 210 and the second bridge 220 may rotate as the first rail 217 and the second rail 227 rotate. According to embodiments, the direction in which the first bridge 210 rotates and the direction in which the second bridge 220 rotates may be orthogonal to each other.

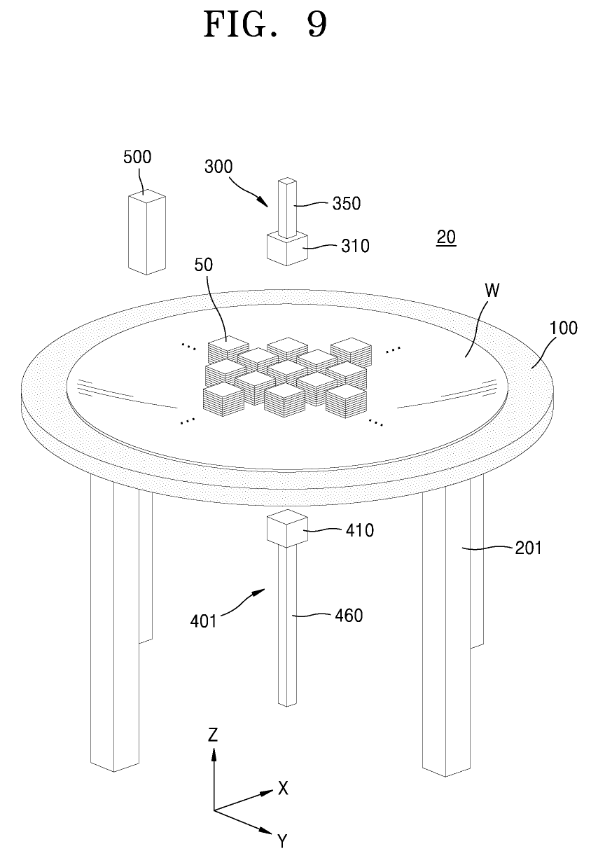

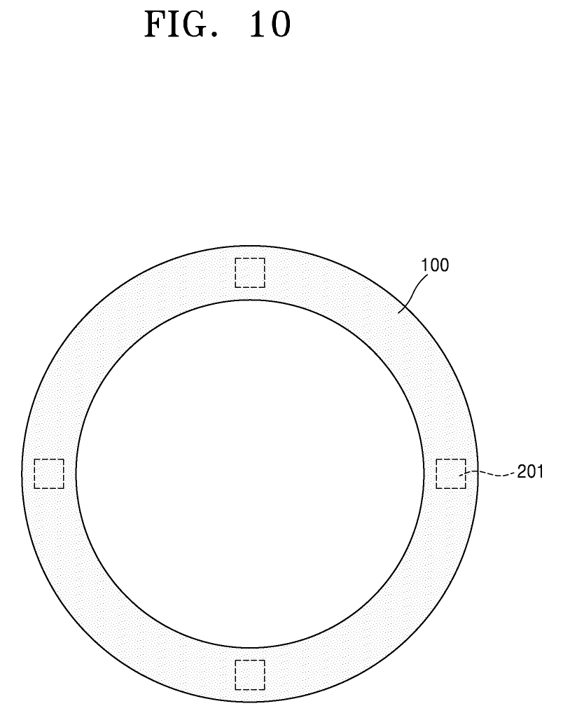

FIG. 9 is a perspective view schematically showing a chip bonding apparatus according to embodiments. FIG. 10 is a plan view schematically showing the support and the tilting member of FIG. 9. Descriptions identical to those already given above with reference to FIGS. 1 - 8 will be omitted, and descriptions below will focus on differences therefrom.

Referring to FIGS. 9 and 10, a chip bonding apparatus 20 may include the support 100, a tilting member 201, a lower bonding member 401, the upper bonding member 300, and the sensor 500.

The support 100 may be configured to support a substrate W. In detail, the support 100 may be configured to support an edge portion of the bottom surface of the substrate W.

According to embodiments, the support 100 may have a disc-like shape having an opening 110 formed in the center. A plurality of chip structures 50 may be positioned on the substrate W. The plurality of chip structures 50 may be positioned to be spaced apart from one another in the horizontal direction X or/and Y. According to embodiments, the substrate W may have a smile warpage shape or a crying warpage shape.

The tilting member 201 may be configured to tilt the support 100. The tilting member 201 may be configured to tilt the support 100 in each of the X-axis direction and the Y-axis direction. The support 100 may have the degree of freedom to tilt in each of the X-axis direction and the Y-axis direction according to the movement of the tilting member 201.

The support 100 may be tilted in any direction around an axis that penetrates through the virtual center of the cross-section of the support 100 along the XY plane in the vertical direction Z by the tilting member 201. Also, the support 100 may be moved horizontally by the tilting member 201.

The tilting member 201 may include a plurality of actuators having a shape extending in the vertical direction Z. According to embodiments, the plurality of actuators may be configured to be coupled to and decoupled from the bottom surface of the support 100. The plurality of actuators may be positioned spaced apart from one another in the horizontal direction X and/or Y. Lengths of the plurality of actuators may increase or decrease in the vertical direction Z. The lengths of the actuators in the vertical direction Z may be increased or decreased. The plurality of actuators may operate independently of one another. Here, the operation may be understood as an operation in which the length of an actuator increases or decreases in the vertical direction Z.

According to embodiments, the tilting member 201 may include four actuators, as shown in FIGS. 9 and 10. The four actuators may be arranged at angles of substantially 90 degrees around the center of the support 100 in a horizontal cross-section. In the same sense, the plurality of actuators may be positioned at 12 o'clock, 3 o'clock, 6 o'clock, and 9 o'clock, respectively, around the center of the support 100 on the cross-section along the XY plane of the support 100.

The plurality of actuators move independently, and the support 100 may be tilted as the lengths of the actuators in the vertical direction Z change. Therefore, the tilting member 201 may arrange the chip structures 50 to be bonded from among the chip structures 50 on the substrate W in a manner parallel to the Z axis.

According to embodiments, the upper bonding member 300 may pressurize and heat the top surface of one chip structure 50. The upper bonding member 300 may include an upper bonding head 310 and an upper bar 350. The upper bonding head 310 may be configured to pressurize and heat the top surface of the chip structure 50 positioned on the substrate W. The upper bar 350 may move the upper bonding head 310 in the vertical direction Z.

The lower bonding member 401 may be positioned to face the bottom surface of the substrate W. The lower bonding member 401 may include the lower bonding head 410 and a lower bar 460. The lower bonding head 410 may be configured to pressurize and heat at least a portion of the bottom surface of the substrate W. The lower bar 460 may have a shape extending in the vertical direction Z.

Unlike the chip bonding apparatus 10 of FIGS. 1 - 6, the chip bonding apparatus 20 of FIGS. 9 and 10 has the tilting member 201 that extends in the vertical direction Z, and thus the lower bonding member 401 may have the lower bar 460 having a columnar shape instead of the support 450 (refer to FIG. 5).

The sensor 500 may be configured to measure the warpage of the substrate W. The sensor 500 may measure the degree of warpage of the substrate W.

The chip bonding apparatus 20 according to the inventive concept may include the tilting member 201 including a plurality of actuators having a shape extending in the vertical direction Z. The tilting member 201 may tilt the support 100 according to the operation of plurality of actuators. Therefore, the chip structure 50 to be bonded on the substrate W may be tilted parallel to the Z axis. Therefore, the bonding reliability of the chip structure 50 may be improved and the occurrence of cracks within the chip structure 50 may be prevented.

Also, since the tilting member 201 includes a plurality of actuators positioned spaced apart from one another, the tilting member 201 (?) may not overlap with the lower bonding member 401 in the vertical direction Z. Therefore, the lower bonding member 401 may be freely driven regardless of the position of the tilting member 201.

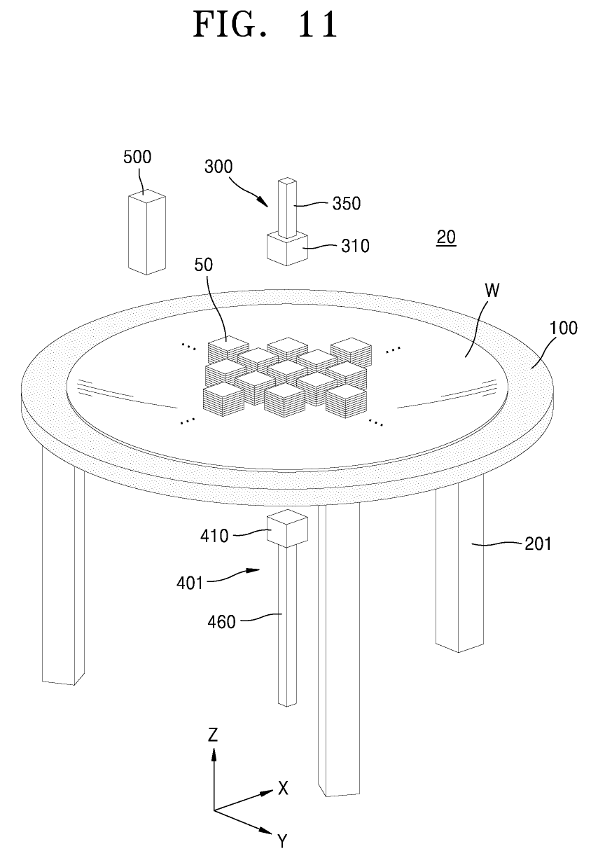

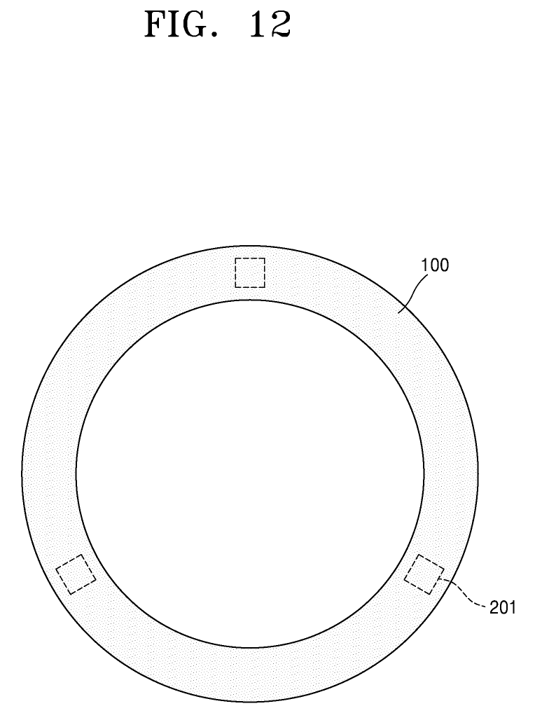

FIG. 11 is a schematic perspective view of a chip bonding apparatus according to embodiments. FIG. 12 is a plan view schematically showing the support and the tilting member of FIG. 11. Descriptions identical to those already given above with reference to FIGS. 9 and 10 will be omitted, and descriptions below will focus on differences therefrom.

Referring to FIGS. 11 and 12 , a chip bonding apparatus 20 may include the tilting member 201, the lower bonding member 401, the upper bonding member 300, and the sensor 500.

The support 100 may be configured to support a substrate W. In detail, the support 100 may be configured to support an edge portion of the bottom surface of the substrate W. According to embodiments, the support 100 may have a disc-like shape having an opening 110 formed in the center. The tilting member 201 may be configured to tilt the support 100. The tilting member 201 may be configured to tilt the support 100 in each of the X-axis direction and the Y-axis direction. The support 100 may have the degree of freedom to tilt in each of the X-axis direction and the Y-axis direction according to the movement of the tilting member 201.

The support 100 may be tilted in any direction around an axis that penetrates through the virtual center of the cross-section of the support 100 along the XY plane in the vertical direction Z by the tilting member 201. Also, the support 100 may be moved horizontally by the tilting member 201.

The tilting member 201 may include a plurality of actuators having a shape extending in the vertical direction Z. According to embodiments, the plurality of actuators may be configured to be coupled to and decoupled from the bottom surface of the support 100. The plurality of actuators may be positioned spaced apart from one another in the horizontal direction X and/or Y. Lengths of the plurality of actuators may increase or decrease in the vertical direction Z. The lengths of the actuators in the vertical direction Z may be increased or decreased. The plurality of actuators may operate independently of one another.

According to embodiments, the tilting member 201 may include three actuators, as shown in FIGS. 11 and 12. The three actuators may be arranged at angles of substantially 120 degrees around the center of the support 100 in a cross-section along the XY plane of the support 100. According to embodiments, virtual lines connecting three actuators to one another may form a triangle.

The plurality of actuators move independently, and the support 100 may be tilted as the lengths of the actuators in the vertical direction Z change. Therefore, the tilting member 201 may arrange the chip structures 50 to be bonded from among the chip structures 50 on the substrate W in a manner parallel to the Z axis.

According to embodiments, the upper bonding member 300 may pressurize and heat the top surface of one chip structure 50. The upper bonding member 300 may include an upper bonding head 310 and an upper bar 350. The upper bonding head 310 may be configured to pressurize and heat the top surface of the chip structure 50 positioned on the substrate W. The upper bar 350 may move the upper bonding head 310 in the vertical direction Z.

The lower bonding member 401 may be positioned to face the bottom surface of the substrate W. The lower bonding member 401 may include the lower bonding head 410 and a lower bar 460. The lower bonding head 410 may be configured to pressurize and heat at least a portion of the bottom surface of the substrate W. The lower bar 460 may have a shape extending in the vertical direction Z.

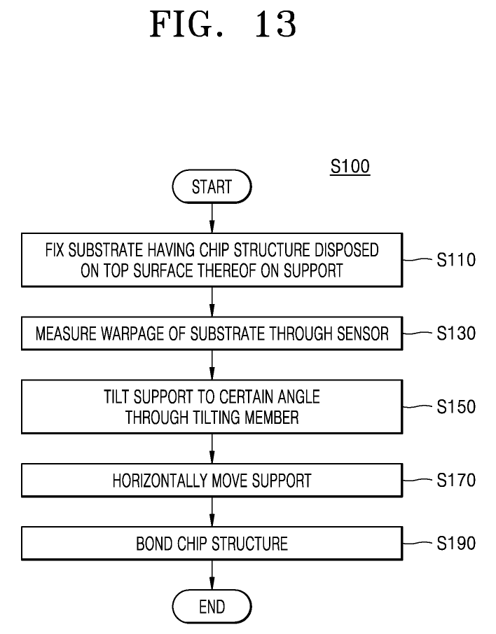

FIG. 13 is a flowchart for describing a chip bonding method according to embodiments. Descriptions identical to those already given above with reference to FIGS. 1 - 12 will be omitted, and descriptions below will focus on differences therefrom. Also, to describe the chip bonding method, FIGS. 1 - 12 will also be referred to together.

Referring to FIGS. 1 - 13, a chip bonding method S100 may include fixing a substrate having a chip structure arranged on a top surface onto a support (operation S110), measuring the warpage of the substrate through a sensor (operation S130), tilting the support at a certain angle through a tilting member (operation S150), horizontally moving the support (operation S170), and bonding the chip structure (operation S190).

The operation S110 for fixing a substrate having a chip structure arranged on the top surface of the substrate onto the support may be performed by fixing the edge of the bottom surface of the substrate W through an adsorption portion of the support 100. The support 100 may have a circular ring-like shape when viewed from above in the vertical direction Z. The substrate W may have a smile warpage shape. Therefore, the vertical level of the bottom surface of the center of the substrate W may be lower than the vertical level of the bottom surface of the edge of the substrate W. Since the support 100 has a circular ring-like shape, even when the substrate W has a smile warpage shape, the substrate W may be easily fixed onto the support 100.

The operation S130 for measuring the warpage of a substrate through a sensor may be performed by measuring the warpage of the substrate W fixed onto the support 100 by using the sensor 500. The sensor 500 may transmit a measured degree of warpage of the substrate W to the controller 600.

The sensor 500 may measure the degree of warpage of the substrate W immediately after the substrate W is fixed onto the support 100. According to some embodiments, the sensor 500 may measure the degree of warpage of the substrate W from time to time. For example, the sensor 500 may measure the warpage of the substrate W again after bonding of one of the plurality of chip structures 50 is performed. Therefore, the reliability of chip bonding may be further improved.

The operation S150 for tilting the support at a certain angle through the tilting member may be performed by the tilting members 200 and 201 having a degree of freedom to tilt in the X-axis and the Y-axis, respectively. According to embodiments, the tilting member 200 may tilt the support 100 through the first bridge 210 and the second bridge 220, as shown in FIGS. 1 - 3. According to embodiments, the tilting member 201 may tilt the support 100 via a plurality of actuators as shown in FIGS. 9 -12.

The support 100 may be tilted by the tilting members 200 and 201 such that the chip structure 50 to be bonded is parallel to the Z axis.

The operation S170 for horizontally moving the support may be performed by horizontally moving the tilting members 200 and 201. Since description thereof is identical to those given above with reference to FIGS. 1 - 12, detailed descriptions thereof will be omitted.

The operation S190 for bonding the chip structure may be performed by moving the upper bonding member 300 and the lower bonding member 400 in the vertical direction Z to pressurize and heat the chip structure 50. The top surface of the chip structure 50 may be pressurized and heated by the upper bonding member 300, and the bottom surface of the chip structure 50 may be pressurized and heated through a process in which the lower bonding member 400 presses and heats the bottom surface of the substrate W that overlaps the chip structure 50 in the vertical direction Z.

While the inventive concept has been particularly shown and described with reference to embodiments thereof, it will be understood that various changes in form and details may be made therein without departing from the spirit and scope of the following claims.

What is claimed is:

1. A chip bonding apparatus comprising:
a support configured to fix an edge portion of a bottom surface of a substrate on which a plurality of chip structures are positioned;
a tilting member configured to tilt the support;
a sensor configured to measure a degree of warpage of the substrate;
an upper bonding member positioned to face a top surface of the substrate and configured to pressurize and heat a top surface of the chip structures; and
a lower bonding member positioned to face the bottom surface of the substrate and configured to pressurize and heat at least a portion of the bottom surface of the substrate,
wherein the tilting member tilts the support such that an axis vertically penetrating through a horizontal cross-section of the support is tilted from the Z-axis.

2. The chip bonding apparatus of claim 1, wherein the tilting member comprises a first bridge and a second bridge,
each of the first bridge and the second bridge has a vertical cross section having a semicircular ring-like shape,
the first bridge and the second bridge are orthogonal to each other when viewed from above in a vertical direction, and
the support is tilted according to rotations of the first bridge and the second bridge.

3. The chip bonding apparatus of claim 2, wherein an inner diameter of the first bridge is greater than an outer diameter of the second bridge.

4. The chip bonding apparatus of claim 2, further comprising a first driving unit configured to provide power to rotate the first bridge around the X-axis, and a second driving unit configured to provide power to rotate the second bridge around the Y-axis.

5. The chip bonding apparatus of claim 4,
wherein two first driving units are provided and are positioned at the same distance from the center of the first bridge, and
wherein two second driving units are provided and are positioned at the same distance from the center of the second bridge.

6. The chip bonding apparatus of claim 2, wherein the lower bonding member comprises a lower bonding head, a connecting bar extending horizontally on a bottom surface of the lower bonding head, and support bars extending vertically downward from one end and the other end of the connecting bar, respectively.

7. The method of claim 1, wherein the tilting member comprises a plurality of actuators that are coupled to the bottom surface of the support, have a shape extending in a vertical direction, have lengths adjusted in the vertical direction, are provided spaced apart from one another, and operate independently of one another.

8. The chip bonding apparatus of claim 7, wherein the plurality of actuators are four actuators and the four actuators and the four actuators are arranged at an angle of 90 degrees around the center of the support in a horizontal cross-section.

9. The chip bonding apparatus of claim 7,
wherein the plurality of actuators are three actuators and the three actuators are arranged at an angle of 120 degrees around the center of the support in a horizontal cross-section.

10. The chip bonding apparatus of claim 7, wherein the lower bonding member comprises a lower bonding head and a lower bar coupled to a bottom surface of the lower bonding head and extending in a vertical direction.

11. The chip bonding apparatus of claim 1, wherein the support has a circular ring-like shape having an opening at the center thereof.

12. The chip bonding apparatus of claim 1, wherein the tilting member is coupled to and separated from the support.

13. The chip bonding apparatus of claim 1, further comprising a controller configured to control the tilting member to be tilted such that the chip structures are parallel to the Z axis based on the degree of warpage of the substrate provided from the sensor.

14. A chip bonding apparatus comprising:
a support configured to fix an edge portion of a bottom surface of a substrate having a smile warpage shape and on which a plurality of chip structures are positioned;
a sensor configured to measure a degree of warpage of the substrate;
a tilting member configured to tilt the support such that an axis vertically penetrating through a horizontal cross section of the support is tilted from the Z axis, and to horizontally and vertically move the support;
an upper bonding member positioned to face a top surface of the substrate and configured to pressurize and heat a top surface of the chip structures; and
a lower bonding member positioned to face the bottom surface of the substrate and configured to pressurize and heat at least a portion of the bottom surface of the substrate,
wherein each of the upper bonding member and the lower bonding member moves in the vertical direction, and
wherein the tilting member is coupled to and separated from the support.

15. The chip bonding apparatus of claim 14, wherein the tilting member comprises a first bridge and a second bridge,
each of the first bridge and the second bridge has a vertical cross section having a semicircular ring-like shape,
the first bridge and the second bridge are orthogonal to each other when viewed from above in the vertical direction, and
the support is tilted according to rotations of the first bridge and the second bridge.

16. The chip bonding apparatus of claim 15, wherein the first bridge comprises a first rail,
the second bridge comprises a second rail,
a power member is located between the first bridge and the second bridge, and
the power member rotates the first rail and the second rail.

17. The chip bonding apparatus of claim 14, wherein the tilting member comprises a plurality of actuators that are coupled to the bottom surface of the support, have a shape extending in the vertical direction, have lengths adjusted in the vertical direction, are provided spaced apart from one another, and operate independently of one another.

18. The chip bonding apparatus of claim 17, wherein the lower bonding member does not overlap the tilting member in the vertical direction.

19. The chip bonding apparatus of claim 17, wherein the plurality of actuators are four actuators and the four actuators are arranged at an angle of 90 degrees around the center of the support in a horizontal cross-section.

20. A chip bonding apparatus comprising:
a support configured to fix an edge portion of a bottom surface of a substrate having a smile warpage shape and on which a plurality of chip structures are positioned;
a tilting member configured to tilt the support such that an axis vertically penetrating through a horizontal section of the support is tilted from the Z-axis, move the support horizontally and vertically. and comprising a first bridge and a second bridge each having a semicircular ring-like shape in a vertical section;
a sensor configured to measure a degree of warpage of the substrate;
an upper bonding member positioned to face a top surface of the substrate and configured to pressurize and heat a top surface of the chip structures;
a lower bonding member positioned to face the bottom surface of the substrate, configured to pressurize and heat at least a portion of the bottom surface of the substrate, and comprising a lower bonding head, a connecting bar extending horizontally on a bottom surface of the lower bonding head, and support bars extending vertically downward from one end and the other end of the connecting bar, respectively; and
a controller configured to control the tilting member to be tilted such that the chip structures are parallel to the Z axis based on the degree of warpage of the substrate provided from the sensor,
wherein the first bridge and the second bridge are orthogonal to each other when viewed from above in the vertical direction,
an inner diameter of the first bridge is greater than an outer diameter of the second bridge, and
the tilting member further comprises a first driving unit configured to rotate the first bridge around the X-axis, and a second driving unit configured to rotate the second bridge around the Y-axis.
